(19) United States
(12) Patent Application Publication
(10) Pub. No.: US 2016/0300928 A1
(43) Pub. Date: Oct. 13, 2016

(54) DENSELY PACKED TRANSISTOR DEVICES

(71) Applicant: GLOBALFOUNDRIES Inc., Grand Cayman (KY)

(72) Inventors: Jan Hoentschel, Dresden (DE); Stefan Flachowsky, Dresden (DE); Peter Javorka, Radeburg (DE); Ralf Richter, Radebeul (DE)

(21) Appl. No.: 14/684,559

(22) Filed: Apr. 13, 2015

(51) Int. Cl. H01L 29/66; H01L 27/088; H01L 21/266; H01L 21/8234; H01L 21/265

(52) U.S. Cl. CPC H01L 29/66545; H01L 21/823437; H01L 21/823418; H01L 29/665; H01L 29/6656; H01L 21/26513; H01L 21/266; H01L 27/088

(57) ABSTRACT

A method of manufacturing a semiconductor device is provided including forming replacement gates over a semiconductor layer, forming sidewall spacers at sidewalls of the replacement gates, forming a dielectric layer in interspaces between the sidewall spacers of neighboring replacement gates, removing the replacement gates and sidewall spacers to form openings in the dielectric layer, and forming gate electrodes in the openings.

### BACKGROUND OF THE INVENTION

1. Field of the Invention

Generally, the present disclosure relates to the field of integrated circuits and semiconductor devices, and, more particularly, to transistor devices that may be densely packed.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout. In a wide variety of electronic circuits, field effect transistors represent one important type of circuit element that substantially determines performance of the integrated circuits. Generally, a plurality of process technologies are currently practiced for forming field effect transistors, wherein, for many types of complex circuitry, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. Miniaturization and increase of circuit densities represent ongoing demands.

A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed between the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, the distance between the source and drain regions, which is also referred to as channel length. Hence, in combination with the capability of rapidly creating a conductive channel below the insulating layer upon application of the control voltage to the gate electrode, the conductivity of the channel region substantially affects the performance of MOS transistors. Thus, as the speed of creating the channel, which depends on the conductivity of the gate electrode, and the channel resistivity substantially determine the transistor characteristics, the scaling of the channel length is a dominant design criterion for accomplishing an increase in the operating speed of the integrated circuits. Downscaling of the channel length and a high integration density of transistor devices becomes more and more important in order to significantly increase the overall performance of semiconductor devices and integrated circuits.

In principle, there are two well-known processing methods for forming a planar or 3D transistor with a high-k/metal gate (HK/MG) structure: (1) the so-called “gate last” or “replacement gate” technique; and (2) the so-called “gate first” technique. In general, using the “gate first” technique involves forming a stack of layers of material across the substrate, wherein the stack of materials includes a high-k gate insulation layer, one or more metal layers, a layer of polysilicon and a protective cap layer, e.g., silicon nitride. Thereafter, one or more etching processes are performed to pattern the stack of materials to thereby define the basic gate structures for the transistor devices. In the replacement gate technique, a so-called “dummy” or sacrificial gate structure is initially formed and remains in place as many process operations are performed to form the device, e.g., the formation of doped source/drain regions, performing an anneal process to repair damage to the substrate caused by the ion implantation processes and to activate the implanted dopant materials. At some stage of the process flow, the sacrificial gate structure is removed to define a gate cavity where the final HK/MG gate structure for the device is formed.

An example of a conventional gate last processing is illustrated in FIGS. 1a-1d. In the processing stage shown in FIG. 1a, a semiconductor device comprises a plurality of transistors, two of which are shown. A replacement gate 1 is covered by a cap layer 2 that was used for patterning the layer from which the replacement gate 1 was formed. The cap layer 2 may be a nitride layer, for example. Sidewall spacers 3 are formed at sidewalls of the replacement gate 1. Source/drain regions 4 are formed adjacent to the sidewall spacers 3. Next, an inter-layer dielectric (ILD) 5 is formed above the structure (see FIG. 1b) and, after planar back polishing, the structure shown in FIG. 1c results. Subsequently, the replacement gate 1 may be removed and a high-k layer 6 and gate electrode 7 may be formed between the sidewall spacers 3, as illustrated in FIG. 1d.

One may define a gate length G, for example, including the high-k layer 6 at the sidewalls of the gate electrode 7, and distance P between the individual gate electrodes (pitch), for example, including the high-k layer 6 at the sidewalls of the gate electrode 7. As already mentioned above, high integration densities for transistor devices are needed for high-performance semiconductor devices and integrated circuits. The described conventional replacement gate techniques are limited with respect to the achievable minimum pitches.

In view of the situation described above, the present disclosure provides techniques that allow for the manufacture of semiconductor devices with minimized pitches not available in the art.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally the subject matter disclosed herein relates to N-channel and P-channel transistor devices, for example, MOSFETs. Particularly, the described method may be used for the manufacturing of transistor devices within the replacement gate (gate last) techniques.

A method of manufacturing a semiconductor device is provided including forming replacement gates over a semiconductor layer, forming sidewall spacers at sidewalls of the replacement gates, forming a dielectric layer in interspaces between the sidewall spacers of neighboring replacement gates, removing the replacement gates and sidewall spacers to form openings in the dielectric layer, and forming gate electrodes in the openings. The openings may be completely filled with the formed gate electrodes. A gate dielectric may be formed in the openings below the gate electrodes.

Further, a method of forming a plurality of high-k/metal gate transistor devices is provided. According to this method, a semiconductor substrate is provided and replacement gates are formed over the semiconductor substrate. Sidewall spacers are formed at sidewalls of the replacement gates. Dopants are implanted in the semiconductor substrate to form source and drain regions and a dielectric layer is formed over the replacement gates and in interspaces between the sidewall spacers of neighboring replacement gates. The replacement gates and sidewall spacers are removed to form openings in the dielectric layer. A high-k gate dielectric is formed in the openings and metal gates are formed on the high-k gate dielectric layer, thereby filling the openings.

In these exemplary methods, the replacements gates are formed with lateral dimensions in the direction of the gate lengths that are reduced with respect to the lateral dimensions of replacement gates of the art. Thus, the distances of neighboring replacement gates may be reduced as compared to the art. After replacing the replacement gates with physical gate electrodes, including removal of the sidewall spacers, the reduced lateral distances between neighboring replacement gates translate to reduced lateral distances (pitches) of physical gate electrodes as compared to the art.

According to an exemplary embodiment, a semiconductor device includes a plurality of transistor devices, each of the transistor devices comprising a gate electrode without sidewall spacers formed on a semiconductor substrate, and wherein a first one and a second one of the plurality of transistor devices are neighbored from each other by a distance between their gate electrodes of at most 20 nm.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1d illustrate a method for gate last processing according to the art; and

FIGS. 2a-2d illustrate a method of replacement gate processing with minimized pitches according to an example of the present invention.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will, of course, be appreciated that, in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The following embodiments are described in sufficient detail to enable those skilled in the art to make use of the invention. It is to be understood that other embodiments would be evident, based on the present disclosure, and that system, structure, process or mechanical changes may be made without departing from the scope of the present disclosure. In the following description, numeral-specific details are given to provide a thorough understanding of the disclosure. However, it would be apparent that the embodiments of the disclosure may be practiced without the specific details. In order to avoid obscuring the present disclosure, some well-known circuits, system configurations, structure configurations and process steps are not disclosed in detail.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

As will be readily apparent to those skilled in the art upon a complete reading of the present application, the present methods are applicable to a variety of technologies, e.g., NMOS, PMOS, CMOS, etc., and is readily applicable to a variety of devices, including, but not limited to, logic devices, memory devices, etc. Generally, manufacturing techniques and semiconductor devices in which N-channel transistors and/or P-channel transistors are formed are described herein. The manufacturing techniques may be integrated in CMOS manufacturing processes. As will be readily apparent to those skilled in the art upon a complete reading of the present application, the present method is applicable to a variety of technologies, for example, NMOS, PMOS, CMOS, etc., and is readily applicable to a variety of devices, including, but not limited to, logic devices, memory devices, etc., in principle. The techniques and technologies described herein may be utilized to fabricate MOS integrated circuit devices, including NMOS integrated circuit devices, PMOS integrated circuit devices and CMOS integrated circuit devices. In particular, the process steps described herein are utilized in conjunction with any semiconductor device fabrication process that forms gate structures for integrated circuits, including both planar and non-planar integrated circuits. Although the term “MOS” properly refers to a device having a metal gate electrode and an oxide gate insulator, that term is used throughout to refer to any semiconductor device that includes a conductive gate electrode (whether metal or other conductive material) that is positioned over a gate insulator (whether oxide or other insulator) which in turn, is positioned over a semiconductor substrate.

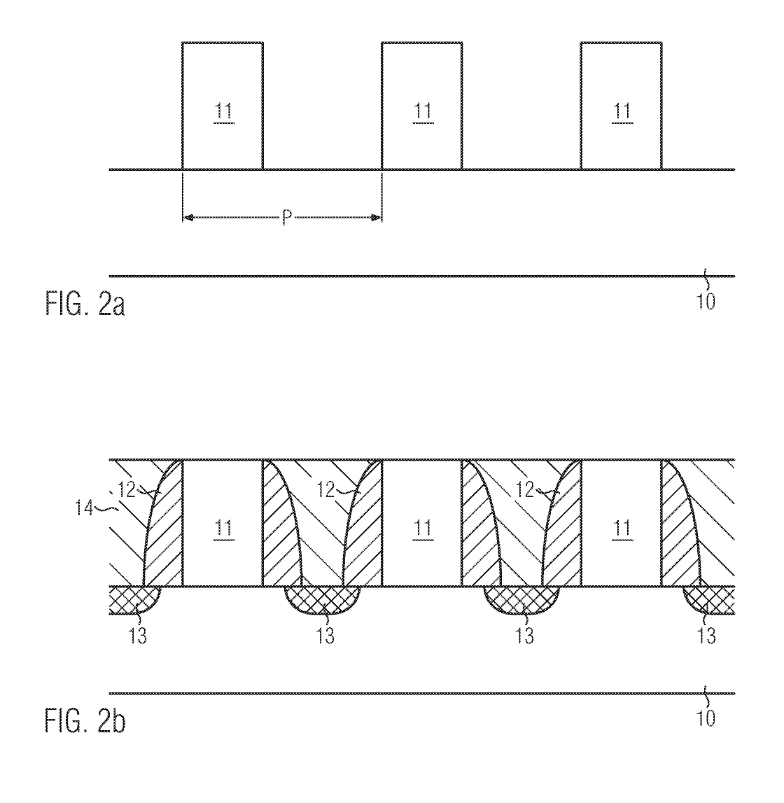

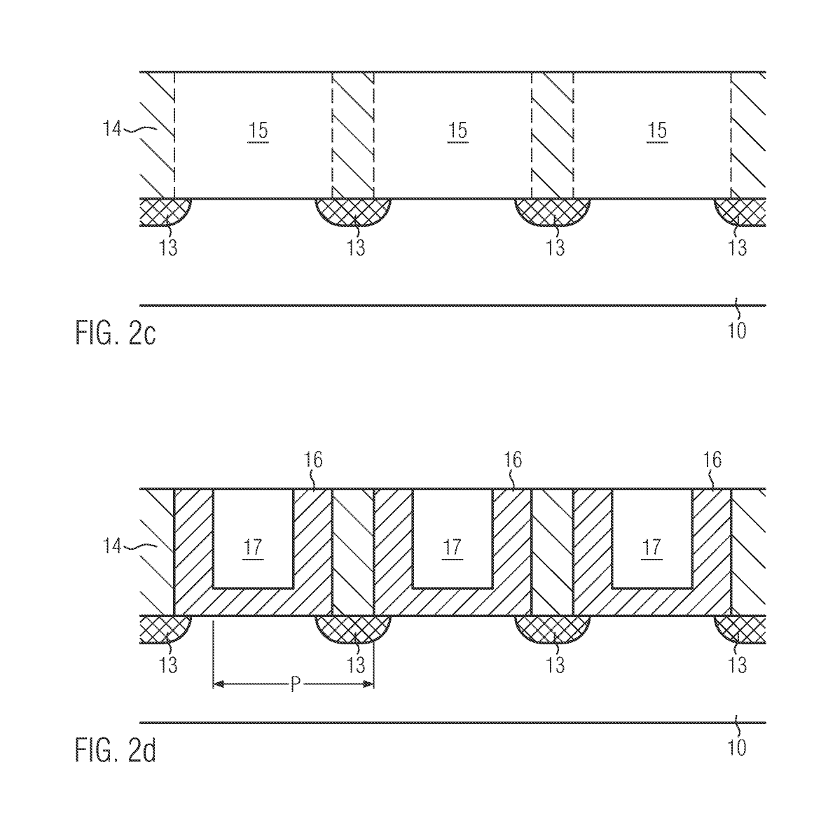

The present disclosure provides methods for the manufacturing of transistor devices with very small pitches, thereby allowing for a high circuit density with densely packed transistor devices. Particular embodiments will be described with reference to FIGS. 2a-2d.

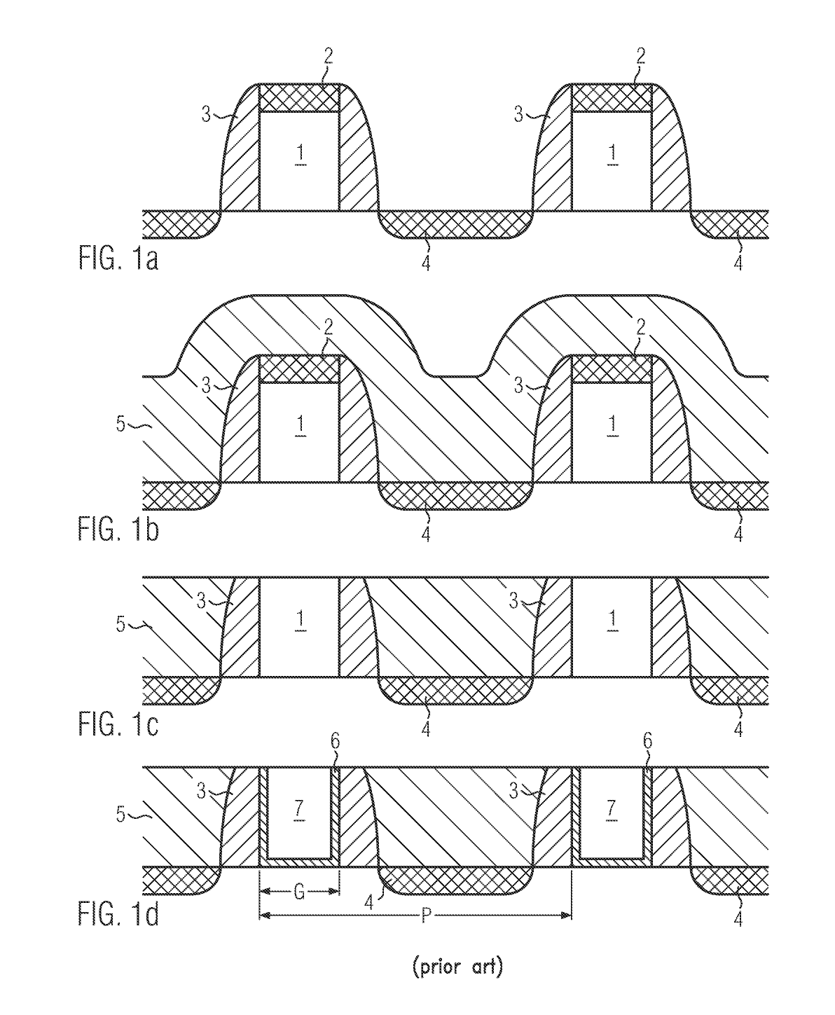

In the manufacturing stage shown in FIG. 2a, replacement gates (dummy gates) 11 are formed from a material layer formed over a substrate 10. The replacement gates 11 are formed by lithographic processing, for example. A mask layer may be formed over the material layer and be appropriately patterned to allow for etching the material layer. As described with reference to FIG. 1a, the replacement gates 11 may be covered by cap layers (not shown in FIG. 2a) used for patterning the material layer from which the replacement gates 11 were formed. The material layer from which the replacement gates 11 are formed may comprise silicon.

Compared to the replacement gates formed in the art (see, for example, FIG. 1a), the gate lengths of the replacement gates 11 of FIG. 2a are significantly reduced. In fact, gate lengths that are not appropriate for the finally formed gate electrodes replacing the replacements gates may be chosen. For example, the gate lengths of the replacement gates 11 may be below 18 or 14 nm. Moreover, the pitch P (distance between individual replacement gates 11, for example, distance from a left edge of a first replacement gate to the left edge of a second adjacent replacement gate positioned right of the first replacement gate) is smaller than the pitch of neighboring replacement gates formed in the art (see, for example, FIG. 1a). For example, the pitch P may be chosen in the range of 38-43 nm. The reduced gate lengths of the replacement gates 11 may, for example, be achieved by over-exposing lines of the lithography resist used for the etching process of the material layer or by over-etching the (poly) replacement gate lines.

The substrate 10 may be a semiconductor substrate. The semiconductor substrate may comprise a semiconductor layer, which in turn may be comprised of any appropriate semiconductor material, such as silicon, silicon/germanium, silicon/carbon, other II-VI or III-V semiconductor compounds and the like. The semiconductor layer may comprise a significant amount of silicon due to the fact that semiconductor devices of high integration density may be formed in volume production on the basis of silicon due to the enhanced availability and the well-established process techniques developed over the last decades.

However, any other appropriate semiconductor materials may be used, for instance, a silicon-based material containing other iso-electronic components, such as germanium, carbon and the like. The semiconductor substrate may be a silicon substrate, in particular, a single crystal silicon substrate. Other materials may be used to form the semiconductor substrate such as, for example, germanium, silicon germanium, gallium phosphate, gallium arsenide, etc. Furthermore, the substrate may define a silicon-on-insulator (SOI) configuration.

In the manufacturing stage shown in FIG. 2b, sidewall spacers 12 are formed at the sidewalls of the replacement gates 11. Each of the sidewall spacers 12 may comprise a layer comprising silicon nitride and/or a layer comprising silicon oxide. According to a particular embodiment, sidewall spacers 12 of Si₃N₄ are formed. The formation of the sidewall spacers 12 may include a substantially isotropic deposition of a layer of a material of the sidewall spacers 12. A material of a liner layer may be deposited by means of a deposition technique, such as atomic layer deposition, before the deposition of the sidewall spacers 12. After the substantially isotropic deposition of the layer of the material of the sidewall spacers 12, an anisotropic etch process, for example, a reactive ion etch process, may be performed for removing portions of the layer over substantially horizontal portions of the surface of the substrate 10 and from the top surfaces of the replacement gates 11 (or cap layers, if provided).

It is noted that the lateral dimensions (from left to right in FIG. 2b) of the replacement gate II plus sidewall spacers 12 might be comparable to the lateral dimension of the replacement gates 1 of the art (see, for example, FIGS. 1a-1c). Since the gate lengths of the replacement gates 11 are smaller as compared to the art, adjacent replacement gates 11 (including the sidewall spacers 12) may be formed closer to each other as compared to the art without running the risk that sidewall spacers 12 of adjacent replacement gates 11 undesirably merge with each other.

The sidewall spacers 12 are provided for adjusting source and drain regions 13 that are formed by appropriate ion implantation as known in the art. Ion implantation in the context of an embedded SiGe sequence may be carried out in order to form the source and drain regions, for example. In embodiments wherein an N-channel field effect transistor (FET) is to be formed, an N-type dopant, such as phosphor (P) or arsenic (As), may be implanted. In embodiments wherein a P-channel FET has to be formed, the substrate 10 may be doped with a P-type dopant, such s boron, for example. The source and drain regions 13 may represent doped silicon-based semiconductor regions. Halo and well regions as well as source drain extensions may also be formed in the substrate 10 depending on the desired transistor operation characteristics.

A thermal annealing process, such as a rapid thermal anneal, wherein the semiconductor structure is irradiated with radiation from a lamp or a laser, may be performed after the formation of the source and drain regions 13. The annealing process may be performed at a temperature in a range from about 550-700° C., and may be performed for a time in a range from about 15-45 minutes.

An annealing process may be carried out that causes a diffusion of a portion of the dopants. Since dopants may diffuse both in a thickness direction of the substrate 10 and in lateral directions perpendicular to the thickness direction of the substrate 10 (horizontal in the plane of FIG. 2b), dopants may diffuse into portions of the substrate 10 below the sidewall spacers 12 and/or below the replacement gates 11. Temperature and duration of the annealing process have to be selected such that there are central portions below the replacement gates 11 into which substantially no diffusion of dopants occurs. These central portions provide the channel regions of eventually completely formed transistor devices.

The conductivity of the source and drain regions 13 may be increased by providing a metal silicide therein in order to reduce overall sheet resistance and contact resistivity. For example, the drain and source regions may receive a metal silicide, such as nickel silicide, nickel platinum silicide and the like, thereby reducing the overall series resistance of the conductive path between the drain and source terminals and the intermediate channel regions of the eventually completely formed transistor devices. The metal silicide regions may be formed on the basis of refractory metals, such as nickel, platinum and the like, that may be deposited and may be converted into a metal silicide by performing an appropriate heat treatment, for example, in the form of a rapid thermal anneal. Thereafter, any non-reacted metal material may be removed on the basis of well-established selective etch techniques, wherein additional heat treatments for stabilizing the overall characteristics may follow, if required. During the silicidation process, the sidewall spacers 12 may reliably cover the sidewalls of the replacement gates 11, thereby avoiding significant metal wraparound such that enhanced controllability and uniformity of the silicidation process may be accomplished.

In the manufacturing state shown in FIG. 2b, a dielectric layer 14 is formed over the replacement gates 11 and in the interspaces between the sidewall spacers 12 of the replacement gates 11. The dielectric layer 14 may be an interlayer dielectric (ILD) and may include a deposited silicon oxide, silicon nitride, or silicon oxynitride, or another material suitable for providing electrical isolation between transistor structures. Tetraethylorthosilicate (TEOS) ILD deposition may be employed. The ILD may be blanket-deposited using, for example, a plasma enhanced chemical vapor deposition (PECVD) process, a low pressure chemical vapor deposition (LPCVD) process, or a chemical vapor deposition (CVD) process. In one embodiment, the ILD includes a silicon oxide material and has a thickness of about 50 nm to about 1 micron, for example a thickness of about 100-500 nm. After planarization of the dielectric layer 14, for example, by chemical mechanical polishing, both the replacement gates 11 and the sidewall spacers 12 are removed. For example, the replacement gates 11, that may be formed of or comprise silicon, are removed in a first etching process and the sidewall spacers 12, that may be formed of silicon nitride, are removed in a second etching process performed, for example, after the first etching process. By removing the replacement gates 11 and sidewall spacers 12, openings 15 are formed, as illustrated in FIG. 2c.

The openings 15 shown in FIG. 2c may be filled by gate electrodes. In the exemplary manufacturing stage illustrated in FIG. 2d, a gate dielectric layer 16 is formed in the openings 15 on the exposed top surface of the substrate 10 and the sidewalls of the openings 15. The gate dielectric layer 16 may include a high-k material having a greater dielectric constant than SiO₂, for example, Hf. The gate dielectric layer 16 may comprise hafnium oxide, hafnium silicon oxide, zirconium oxide, aluminum oxide and the like. The high-k dielectric material layer 16 may have a thickness of one to several nanometers and may be formed by oxidation and/or deposition, depending on the materials required.

A gate layer 17 is formed on or over the dielectric material layer 16, as shown in FIG. 2d. The openings 15 may be completely filled with the dielectric material layer 16 and the gate layer 17. The gate layer 17 may comprise a metal gate. The material of the metal gate may depend on whether the transistor device to be formed is a P-channel transistor or an N-channel transistor. In embodiments wherein the transistor device an N-channel transistor, the metal may include La, LaN or TiN. In embodiments wherein the transistor device is a P-channel transistor, the metal may include Al, AlN or TiN. The metal gate may include a work function adjusting material, for example, TiN. In particular, the metal may comprise a work function adjusting material that comprises an appropriate transition metal nitride, for example, those from Groups 4-6 in the Periodic Table, including, for example, titanium nitride (TiN), tantalum nitride (TaN), titanium aluminum nitride (TiAlN), tantalum aluminum nitride (TaAlN), niobium nitride (NbN), vanadium nitride (VN), tungsten nitride (WN), and the like, with a thickness of about 1-60 nm. Moreover, the effective work function of the metal gate 17 may be adjusted by added impurities, for example, Al, C or F. Moreover, the gate layer 17 may comprise a polysilicon gate at the top of the metal gate.

The lateral dimensions (from left to right in FIG. 2d) of the gate structure comprising the gate layers 17 and dielectric material layers 16 as shown on FIG. 2d may be comparable to the lateral dimensions of the conventionally formed gate structures including the high-k layer 6 at the sidewalls of the gate electrode 7 as shown in FIG. 1d. However, the distances between individual neighboring gate structures according to the shown example of the invention are significantly reduced as compared to the art. For example, the pitch P measured from a left edge of a first electrode structure to a left edge of a second electrode structure neighbored on the right-hand side of the first gate electrode structure may be reduced by at least 30%, in particular, at least 40%, as compared to the art. Semiconductor devices with transistors exhibiting gate lengths of about 20 nm with pitches of about 40 nm can thus be achieved.

As a result, herein, semiconductor devices and techniques for the manufacturing of the same are provided that show a high circuit density due to significantly reduced space requirements (minimized pitches) for neighboring transistor devices without negatively affecting electrostatic characteristics and the overall operation performance.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method of manufacturing a semiconductor device, the method comprising:
forming replacement gates over a semiconductor layer;
forming sidewall spacers at sidewalls of said replacement gates;
forming a dielectric layer in interspaces between said sidewall spacers of neighboring replacement gates;
removing said replacement gates and said sidewall spacers to form openings in said dielectric layer; and
forming gate electrodes in said openings.

2. The method of claim 1, further comprising forming gate dielectric layers in said openings of said dielectric layer and wherein said gate electrodes are formed over said gate dielectric layers.

3. The method of claim 2, wherein said gate dielectric layer is a high-k dielectric layer with a dielectric constant k of greater than 5.

4. The method of claim 1, wherein said gate electrodes comprise metal-containing layers.

5. The method of claim 1, wherein a first gate electrode of said gate electrodes is formed with a distance to a neighboring second gate electrode of said gate electrodes in the direction of a channel length of said first and second gate electrodes of at most 20 nm.

6. The method of claim 1, further comprising forming source and drain regions in said semiconductor layer before the formation of said dielectric layer and at least partly after the formation of said sidewall spacers.

7. The method of claim 6, further comprising silicidating the formed source and drain regions.

8. The method of claim 1, wherein said dielectric layer is an interlayer dielectric comprising an oxide material.

9. The method of claim 1, wherein removing said replacement gates and said sidewall spacers to form said openings in said dielectric layer comprises etching said replacement gates in a first etching process and etching said sidewall spacers in a second etching process different from said first etching process.

10. The method of claim 9, wherein, during said first etching process, a silicon material is etched and, during said second etching process, a nitride material is etched.

11. A method of forming a plurality of high-k/metal gate transistor devices, the method comprising:
providing a semiconductor substrate;
forming replacement gates over said semiconductor substrate;
forming sidewall spacers at sidewalls of said replacement gates;
implanting dopants in said semiconductor substrate to form source and drain regions;
forming a dielectric layer over said replacement gates and in interspaces between said sidewall spacers of neighboring replacement gates;
removing said replacement gates and said sidewall spacers to form openings in said dielectric layer;
forming a high-k gate dielectric in said openings; and
forming metal gates on said high-k gate dielectric.

12. The method of claim 11, further comprising forming polysilicon gates on said metal gates.

13. The method of claim 11, wherein a first gate electrode of said metal gates is formed with a distance to a neighboring second gate electrode of said metal gates in the direction of a channel length of said first and second gate electrodes of at most 20 nm.

14. The method of claim 11, wherein said sidewall spacers are used as implantation masks for said implanting of said dopants.

15.-16. (canceled)
